(19) United States
(12) Patent Application Publication
(10) Pub. No.: US 2015/0173256 A1
(43) Pub. Date: Jun. 18, 2015

(54) EMI SUPPRESSION TECHNIQUE USING A TRANSMISSION LINE GRATING

(71) Applicant: Lenovo Enterprise Solutions (Singapore) Pte. Ltd., Singapore (SG)

(72) Inventors: Eric R. Ao, Nepean (CA); Alexander P. Campbell, Kanata (CA); Donald R. Dignam, Ottawa (CA); Jian Meng, Kanata (CA); Stephen J. Flint, Ottawa (CA)

(21) Appl. No.: 14/109,440

(22) Filed: Dec. 17, 2013

(51) Int. Cl. H05K 9/00; G06F 17/50; H05K 1/02

(52) U.S. Cl. CPC H05K 9/009; H05K 1/0216; G06F 17/5077; G06F 17/5081; G06F 2217/82; G06F 2217/02; G06F 2217/06

(57) ABSTRACT

The present invention proposes methods and structures for designing electronic circuit elements for frequency suppression of electromagnetic waves using a transmission line grating. The method includes determining a frequency to be suppressed. Using the electrical wavelength of the frequency to be suppressed, determine a length of a plurality of equal length sections of the differential transmission lines is determined. Using the frequency to be suppressed and the electronic circuit requirements, determine a set of properties for the plurality of equal length sections of the differential transmission lines. The transmission line grating is created using a plurality of alternating equal length sections of the differential transmission lines.

### FIELD OF THE INVENTION

The present invention relates generally to the field of printed circuit board design, and more particularly to reducing EMI in high frequency printed circuit board design.

### BACKGROUND OF THE INVENTION

Electromagnetic interference (EMI) is the generation of undesired electrical signals in electronic system circuitry when an electromagnetic (EM) wave in one electrical circuit, component or part is unintentionally transferred to another electrical circuit, component or part. As electronic systems are evolving, the density of electrical components in these systems is increasing, and the dimensions of circuit elements correspondingly decrease. As spacing decreases between circuit elements, the likelihood of interference from adjacent circuit elements increases.

Circuit elements are effective in radiating electromagnetic energy or spectral components which have wavelengths similar to the radiating element dimensions. Therefore, as electronic system size decreases and electronic system density increases, electromagnetic emissions occur in greater strength from the system. The current market direction for electronic devices with increasing operating frequencies are moving from the gigahertz (GHz) range to 10 GHz and greater while the devices decrease in size, creates significant EM radiation generation opportunities in electronic devices. With the increasing demand for high speed and portable devices, the reduction of EMI is becoming a larger design consideration.

Electronic product manufacturers take several approaches to minimizing EMI for electromagnetic compatibility compliance. Shielding products to prevent electromagnetic (EM) radiation is a common technique. At the system or board level metal cages or metal covers may be installed to prevent the radiation of electromagnetic waves causing EMI. While commonly done, this can be an awkward and costly solution to meeting EMC requirements. In smaller, portable devices running with higher frequencies, metal covers or shields may be hard to implement. In printed circuit board (PCB) design, placement of high frequency devices may be planned to avoid devices sensitive to EMI. Careful device placement may reduce the size of card covers used to reduce EMI. Designs that focus on suppression of unwanted electromagnetic radiation can provide a more cost effective solution to reducing EMI. Suppression of EMI before is it transmitted outside of the system or enclosure is critical to EMC compliance.

The generation of excess EM radiation in devices is problematic to other components within the electronic device and to other nearby electronic devices. Unwanted signals generated from excess EM radiation, from within a device and from nearby electronic devices, leads to EMI in electronic devices. For this reason regulatory committees exist both nationally and internationally to monitor and define limits of allowable EMI for various electronic devices. Requirements and tests are defined for electromagnetic compatibility (EMC) that monitor EM radiation causing EMI between systems and components for electronic devices.

### SUMMARY

The present invention provides methods and structures to design electronic circuit elements for frequency suppression of electromagnetic waves using a transmission line grating. The method includes determining a frequency to be suppressed. Using the electrical wavelength of the frequency to be suppressed to determine a length of a plurality of equal length sections of the differential transmission lines. Utilizing the frequency to be suppressed and the electronic circuit requirements, determine a set of properties for the plurality of equal length sections of the differential transmission lines. The transmission line grating is created with a plurality of alternating equal length sections of the differential transmission lines.

### BRIEF DESCRIPTION OF THE SEVERAL VIEWS OF THE DRAWINGS

FIG. 1 is a cross-sectional view of a strip-line design of a differential transmission lines in accordance with an embodiment of the present invention.

FIG. 2 depicts a top view of a transmission line grating in accordance with an embodiment of the present invention.

FIG. 3 is a flow chart illustrating steps of a method to design a transmission line grating in accordance with an embodiment of the present invention.

FIG. 4 is a flow chart illustrating steps of a method to design a transmission line grating in accordance with another embodiment of the present invention.

FIG. 5 is a graph of a simulation of common mode insertion loss in a differential transmission lines with and without a transmission line grating.

FIG. 6 is a graph of a simulation of differential mode insertion loss in a differential transmission lines with and without a transmission line grating.

### DETAILED DESCRIPTION

Embodiments of the present invention provide methods and structures for suppression of electromagnetic waves using a transmission line grating design technique. In particular, some embodiments of the present invention provide methods and structures for suppression of specific frequencies of the common mode electromagnetic waves using a transmission line grating technique. One skilled in the art will recognize that concepts developed in exemplary embodiments of the present invention could be applied to other multilayered circuit substrates, for example laminate chip carrier design, ceramic chip carrier design, flex cables, and other multilayer circuit substrates including semiconductor design applications.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, and some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

The transmission line grating design technique described in the present invention is used to suppress targeted frequencies of electromagnetic waves. The suppression of targeted electromagnetic wave frequency in a circuit reduces the electromagnetic radiation produced by electronic devices. More specifically, targeted or selected frequencies of the common mode electromagnetic waves in a circuit may be used to reduce electromagnetic radiation produced by the electronic devices. The elimination of a targeted frequency or frequencies that are generating unwanted electromagnetic waves or noise in an electronic circuit aid in the reduction of EMI. EMI reduction is increasingly important in high speed, high frequency electronics products where miniaturization and portability drive much of the marketplace.

The transmission line grating technique described herein can be applied to numerous applications in electronics. The transmission line grating may be applied to PCB board design, flexible cable design, chip carrier design, chip design or other electronic components that can utilize differential pair transmission lines. The transmission line grating technique described requires little to no change to existing manufacturing lines and little additional cost to the component. The specific embodiments described in this application address the application of this technique in PCB design; however, one skilled in the art can apply this concept to other electronic devices. For example, a flexible cable using a transmission line grating may be design and manufactured. A flexible cable using the transmission line grating technique reduces noise from suppressed frequencies within a system and/or the EMI radiated outside of system when the flexible cable is used externally.

In differential transmission lines, there are both common mode and differential mode currents, both of which determine the amount of radio frequency (RF) energy that is developed and propagated. Both common mode and differential mode of currents usually exist in a differential transmission line. The differential mode current or signals carry the data or signal of interest (information). The common mode current which carries no useful information is a side effect or byproduct of the differential mode signal transmission. The common mode AC current or “noise” generates EM radiation which is troublesome for EMC compliance.

Radiated emission for a differential mode current or signal is the component of RF energy that is present on both the signal and return paths that are opposite to each other in differential pairs. In designs using differential signaling, an inverted signal is precisely established so that the common mode AC currents will be cancelled out.

In most high speed signal interconnects, the use of differential signaling includes a differential transmitter, a differential receiver, and a differential data path including differential signal pairs, vias, and eventually connectors and cables. An ideal differential transmitter sends a set of two identical signals with opposite polarity. When this occurs, the amplitude of the differential mode which is the difference of the two signals is double that of the single signal while the AC amplitude of the common mode signal is always zero.

In most real world environments, many things cause a notable or non-zero common mode AC amplitude. In particular, differences in rise and fall times in single-ended signals and the difference in duty cycle of single-ended signals have been observed to create common mode noise around the even harmonics of the fundamental signal frequency in PCBs. The fundamental frequency of a data signal is the inverse of two times the single bit time. Additionally, the fundamental frequency of a clock is the inverse of the period of the clock which may be used in some embodiments.

Other sources of common mode currents may include ground bounce, power plane fluctuations, and differential signals that are not precisely inverted where the portions of the signal that do not cancel out create common mode currents. The common mode current is also present in both the signal and return paths. The RF field resulting from the common mode current is due to the sum of the currents that exist in both the signal and return path. This sum can be substantial since common mode currents lack differential mode cancellation effects.

The transmission line grating technique described herein targets the suppression of a specific frequency, in particular a specific common mode frequency in a circuit, while protecting the differential mode signal from change. Utilizing this transmission line grating technique within a PCB structure effectively suppresses common mode noise while preserving the signal integrity of the differential mode signal. In particular, it can suppress common mode even harmonics radiation, empirically shown as a common source of EMI. Common mode even harmonics radiation, a common source of EMI, is usually caused by imperfections of the output signals of high frequency signal transmitters that show up as a narrow spike in the emissions spectrum. The common mode radiation constitutes a major concern during electromagnetic compatibility (EMC) testing. EMC testing is required of many electronic products and is regulated by standards for each nation with advisory guidance from the International Electrotechnical Commission. The suppression of common mode even harmonic radiation in PCBs before it is transmitted outside of the enclosure or box is critical to pass required EMC tests.

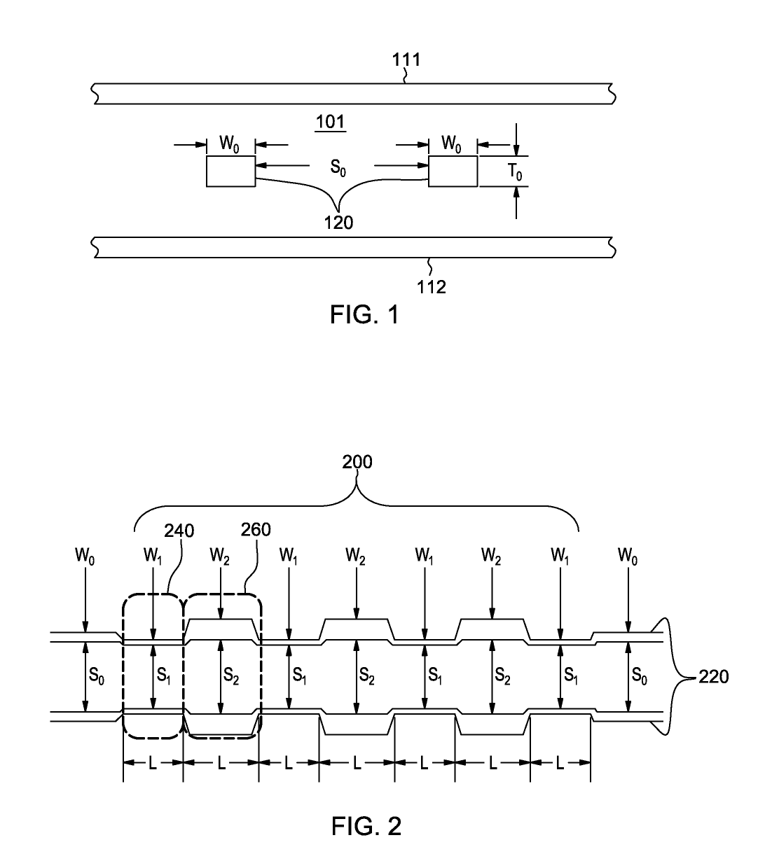

High frequency designs often require the use of differential signaling and differential signal pairs. A differential signal pair is a pair of identical transmission lines. Differential signal pairs generally are symmetrical to each other and their surrounding structures. In general, a differential signal pair will have a constant spacing between each other and are driven from a differential transmitter. The electrical properties of a differential pair, for example characteristic impedance, are defined by the geometric dimensions including line width, line thickness, line spacing and line distance to reference or ground planes and the dielectric material surrounding the pair. Maintaining a constant differential characteristic impedance which closely matches the differential characteristic impedance of the initial differential transmission lines (w0/s0 in FIG. 1) for the differential pair is an important design focus in developing the transmission line grating.

The present invention will now be described in detail with reference to the Figures. FIG. 1 is a cross-sectional view of a strip-line design of differential transmission lines in accordance with an embodiment of the present invention. In the strip-line cross-section shown, the PCB material and the reference planes encapsulates the transmission lines.

In the strip-line cross-section, the transmission lines are surrounded by PCB dielectric material or dielectric layers 101 which are usually composed of epoxy/glass although other dielectric materials may be used. The differential transmission lines 120 and the dielectric layers 101 are covered with reference planes 111 and 112, usually made of copper foil. Reference plane 111 is on top of dielectric layers 101 while reference plane 112 is below dielectric layers 101, thus encasing transmission lines 120 in dielectric layers 101 which are covered with reference planes 111 and 112. Each of the transmission lines in the differential transmission lines 120 has width w0 and thickness t0. The pair of transmission lines 120 have a space, space s0, between them. The thickness of the various layers in the PCB cross-section is determined by system requirements and the manufacturing capabilities for the PCB. While the exemplary embodiment of the present invention uses a strip-line design for the PCB cross-section of the transmission line grating, other embodiments may use a micro-strip design for the cross-section.

FIG. 2 depicts a top view of a transmission line grating in accordance with an embodiment of the present invention. Transmission line grating 200 illustrated in FIG. 2 consists of alternating narrow and wide transmission line sections of equal length L. Initial transmission line width w0, and initial transmission line spacing s0 of the differential transmission lines 220 are determined based on the dielectric materials used in the PCB, the manufacturing process and the desired properties for the circuit. In the transmission line grating design, the differential characteristic impedance is kept uniform along the circuit lines. Transmission line width, w0, and transmission line spacing, s0, are determined by the electronic circuit requirements which include maintaining a uniform differential characteristic impedance in the circuit. The properties of the individual sections of differential transmission lines 220 such as line width and line spacing are adjusted so that the differential characteristic impedance does not change.

The transmission line grating depicted in FIG. 2 is composed of a series of alternating narrow and wide transmission line sections of equal length L. Initial transmission line width w0, and initial transmission line spacing s0 are not a part of transmission line grating 200. The first section, section 240 of transmission lines 220 in transmission line grating 200 has narrow lines with width w1, spacing s1 and section length L. The next section, section 260 of transmission lines 220 in transmission line grating 200 has wide lines with width w2, spacing s2 and section length L. Only one of the section line widths, w1 or w2, in transmission line grating 200 can match the width of the initial transmission line width, w0, but it is not required for either w1 or w2 to match w0. For example both the width w1 and the width w2 may be different than w0. In FIG. 2, the sections of the transmission line 220 with the line width, w1, and the sections of the transmission line 220 with line width, w2, alternate along the length of transmission line grating 200. In other words, as shown in FIG. 2, narrow line sections 240 are followed by wide line sections 260 within transmission line grating 200.

In some embodiments of the invention, there may be more than two different widths and respective spacing for the differential transmission lines. Some transmission line gratings may have alternating sections with multiple different line widths for example.

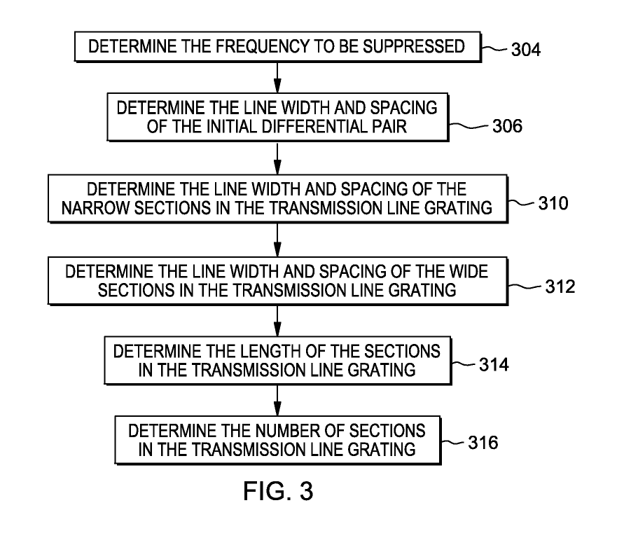

The length of each of the individual sections, length L, is equal to one quarter of the electrical wavelength of the frequency band that is to be suppressed. The frequency to be suppressed and the effective dielectric constant of the material determine the wavelength. For example, in the PCB design shown, the frequency for suppression is the frequency of the second harmonic of the fundamental frequency of the circuit. Accordingly, the length of each section, length L, is equal to one quarter of the wavelength of the second harmonic of the fundamental frequency of the electronic circuit. The steps of a method to create a transmission line grating design are discussed below in FIG. 3.

FIG. 3 is a flow chart describing a method to create a transmission line grating, in accordance with an exemplary embodiment of the present invention.

In step 304, the designer determines the frequency to be suppressed. In an embodiment of the present invention, the transmission line grating is designed to suppress the frequency of the second harmonic frequency of the fundamental frequency; however the transmission line grating technique described may be applied to suppress other frequencies.

In step 306, the designer determines the line width and the line spacing of the initial transmission lines in the differential pair before and after the transmission line grating (e.g., w0 and s0 in FIG. 2, etc.). Standard design practices for high frequency PCB design are applied. The PCB designer trades off line width/spacing, layer thickness, cross-section thickness selection, material properties (e.g., dielectric constant of insulating layers, copper thickness, etc.) based on system requirements, for example, characteristic impedance, clock rate, insertion loss, signal speed, and manufacturing cost to determine a transmission line width and spacing to meet desired requirements. With the optimized trade offs made by the designer, the initial transmission line width and spacing for transmission lines coming into and going out of the transmission line grating are determined. The initial transmission line width and spacing may vary based on system requirements and PCB manufacturer.

In step 310, the designer selects the line width and the line spacing for the narrow line width sections, section 240 of transmission line grating 200. Section 240 illustrates the first section of the sections with line width w1 and line spacing, s1 and length L FIG. 2. The designer may select the smallest line width and spacing practical in the manufacturing process to increase the difference in line widths between the narrow sections and the wide sections. At the same time, the selected line width and line spacing should result in the same or nearly the same differential impedance as the initial differential transmission lines 220 with width w0.

In step 312, the designer selects the line width and the line spacing for the wide line width sections, section 260 of transmission line grating 200. Section 260 illustrates the first section of wide line width sections with line width w2 and spacing s2 as shown in FIG. 2. The designer may select the largest line width and spacing practical in the manufacturing process and allowable with the PCB space requirement. By maximizing the line width of the wide line sections and minimizing the width of the narrow line sections, better EMI suppression may be obtained. At the same time, the selected line widths and line spacing should result in the same or nearly the same differential impedance as the initial differential pair 220.

The transmission line grating consists of alternating equal length sections of narrow and wide transmission lines. The width of either the narrow width lines or the wide width lines may be equal to the width of the initial transmission lines connected to the transmission line grating. Both the width of the narrow width lines (w1 in FIG. 2) and that of the wide width lines (w2 in FIG. 2) may be a different width than the line width of the initial differential pair (w0 in FIG. 2). In general, the narrower the lines in a differential pair for the transmission line grating, the less space is required within the differential pair. Similarly, the wider the line in the transmission line grating, the wider the space within the differential pair. The greater the difference in the widths of the narrow width lines and the widths of the wide width lines in the transmission line grating, the better the frequency suppression.

In step 314, the designer determines the section length for each section of the transmission line grating (e.g., L in FIG. 2, etc.). Each section uses the same section length in the transmission line grating. To determine the section length, the designer uses the electrical wavelength of the frequency of the band to be suppressed. In the exemplary embodiment of the present invention, the section length is one quarter of the electrical wavelength of the frequency to be suppressed. In setting up the transmission line grating in this way, the common mode noise around the second harmonic frequency may be suppressed without affecting the differential mode of the signal. While the second harmonic frequency is selected to be suppressed, in other embodiments, other frequencies and other wavelengths for sections could be selected

In step 316, the designer determines the number of sections to be used in the transmission line grating. The larger the number of sections, the better the selected frequency suppression. The number of sections may be limited by the available card real estate and the cost associated with a larger PCB. The transmission line grating may be placed on any desired internal layer. In other embodiments of the present invention, the transmission line grating may be used on an external surface. When the transmission line grating is used on an external surface, the designer should take into account micro-strip line design characteristics, for example differing dielectric constants, not present in a strip design.

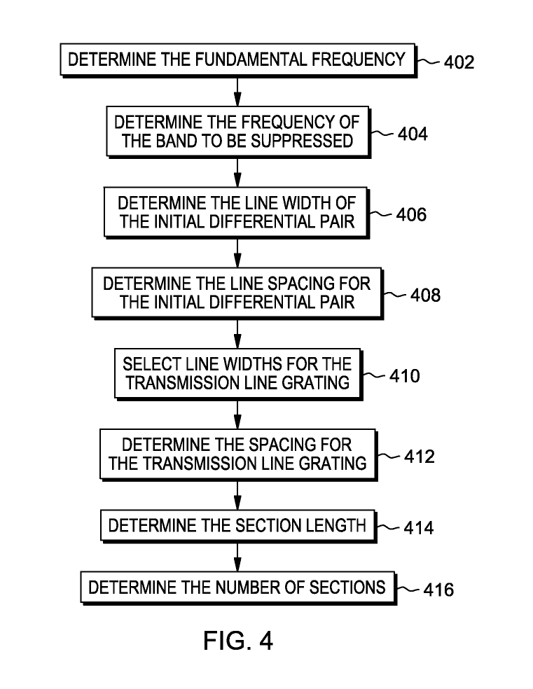

FIG. 4 is a flow chart describing a method to create a transmission line grating, in accordance with another embodiment of the present invention.

In step 402, the designer (e.g., a human designer or a programmatic designer, etc.) determines the fundamental frequency of the transmission lines under design in the PCB.

In step 404, the designer determines the frequency to be suppressed. In an embodiment of the present invention, the transmission line grating is designed to suppress the frequency of the second harmonic frequency of the fundamental frequency; however the transmission line grating technique described may be applied to suppress other frequencies.

In step 406, the designer determines line width of the initial transmission lines in the differential pair before and after the transmission line grating (e.g., w0 in FIG. 2, etc.). Standard design practices for high frequency PCB design are applied. The PCB designer trades off line width/spacing, layer thickness, cross-section thickness selection, material properties (e.g., dielectric constant of insulating layers, copper thickness, etc.) based on system requirements, for example, characteristic impedance, clock rate, insertion loss, signal speed, and manufacturing cost to determine a transmission line width to meet desired requirements. With the optimized trade offs made by the designer, the initial transmission line width for transmission lines coming into and going out of the transmission line grating is determined. The initial transmission line width may vary based on system requirements and PCB manufacturer.

In step 408, the designer determines the line spacing for the initial transmission line of the differential transmission lines (e.g., s0 in FIG. 2, etc.). Using the line width of the initial line width, w0, determined in step 406, and the electrical properties for the circuit including material properties, the designer determines the spacing or space s0 between the initial differential transmission lines.

In step 410, the designer selects the line widths for the transmission line grating (e.g., w1 and w2 in FIG. 2, etc.). The transmission line grating consists of alternating equal length sections of narrow and wide transmission lines. The width of either the narrow lines or the wide lines may be equal to the width of the initial transmission lines in the first differential pair. The narrow width lines (w1 in FIG. 2) and the wide width lines (w2 in FIG. 2) both may be a different width than the width of the first differential pair of lines (w0 in FIG. 2).

In step 412, the designer determines the spacing for the different line widths in the transmission line grating (e.g., s1 and s2 in FIG. 2, etc.). Based on the transmission line width, the line spacing is determined using the electrical performance objectives which include maintaining a uniform differential characteristic impedance in the transmission line and the differential pair. The narrow line spacing and the wide line spacing may be determined such that all sections of the transmission line grating meet the required differential characteristic impedance. In general, the narrower the lines in a differential pair for the transmission line grating, the less space is required between the differential pair. Similarly, the wider the line in the transmission line grating, the wider the space between the differential pair. The greater the difference in the widths of the narrow line and the widths of the wide lines in the transmission line grating, the better the frequency suppression.

The manufacture and cost of the PCB place some limitations on line width and spacing. For example, narrow transmission lines for the grating may have process limits for the PCB manufacturing plant or processes. Additionally, PCB cost targets may limit minimum line widths and spacing. Similarly, line width and line spacing may be limited by the electrical properties fundamental to a differential pair (too far apart the transmission lines are not a pair electrically) while narrow line widths may also introduce too much insertion loss.

In step 414, the designer determines the section length for each section of the transmission line grating (e.g., L in FIG. 2, etc.). Each section uses the same section length in the transmission line grating. To determine the section length, the designer uses the electrical wavelength of the frequency of the band to be suppressed. In the exemplary embodiment of the present invention, the section length is one quarter of the electrical wavelength of the frequency to be suppressed. In setting up the transmission line grating in this way, the common mode noise around the second harmonic frequency may be suppressed without affecting the differential mode of the signal. While the second harmonic frequency is selected to be suppressed, in other embodiments, other frequencies and other wavelengths for sections could be selected

In step 416, the designer determines the number of sections to be used in the transmission line grating. The larger the number of sections, the better the selected frequency suppression. The number of sections may be limited by the available card real estate and the cost associated with a larger PCB. The transmission line grating may be placed on any desired internal layer. In other embodiments of the present invention, the transmission line grating may be used on an external surface. When the transmission line grating is used on an external surface, the designer should take into account micro-strip line design characteristics, for example differing dielectric constants, not present in a strip design.

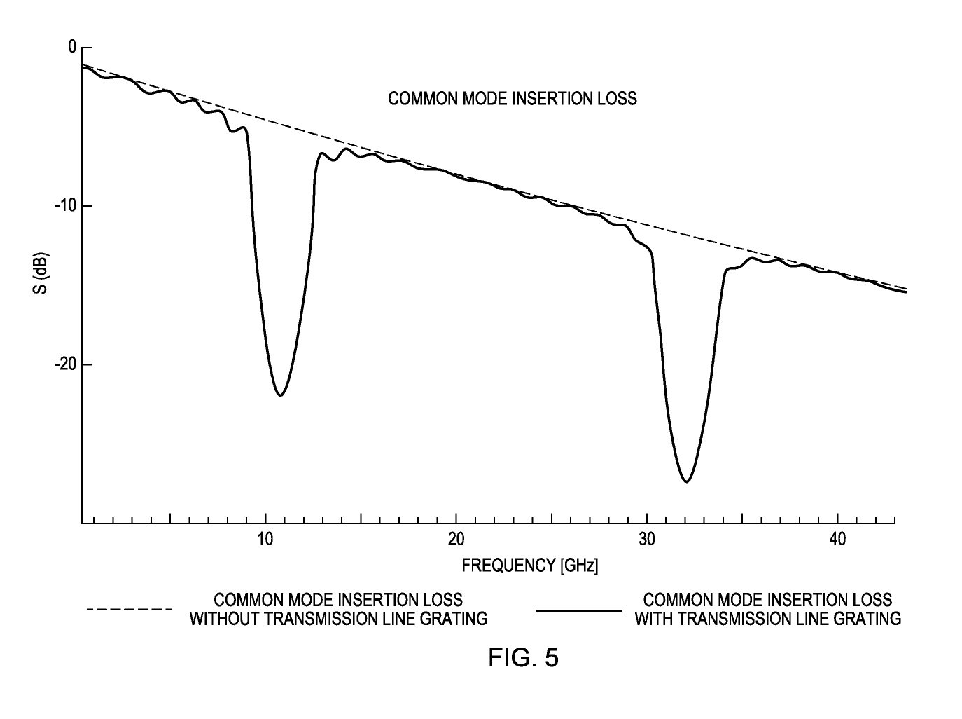

FIG. 5 is a graph of a simulation of common mode insertion loss in differential transmission lines with and without a transmission line grating. The simulation of the insertion loss shown in a representative differential transmission lines with and without a transmission line grating is shown at various frequencies. The same length transmission lines are used for both simulations. The insertion loss is shown on the Y axis in dB and frequency is on the X axis in GHz. The simulation evaluates the insertion loss of common mode signals with and without the transmission line grating. The graph of the simulated data illustrates a significant reduction in the voltage or energy out of the transmission lines due to common mode current at several frequencies with the transmission line grating as shown by the larger magnitude of the insertion loss. The graph depicts the effective suppression of the targeted frequency (10 GHz) in the common mode current.

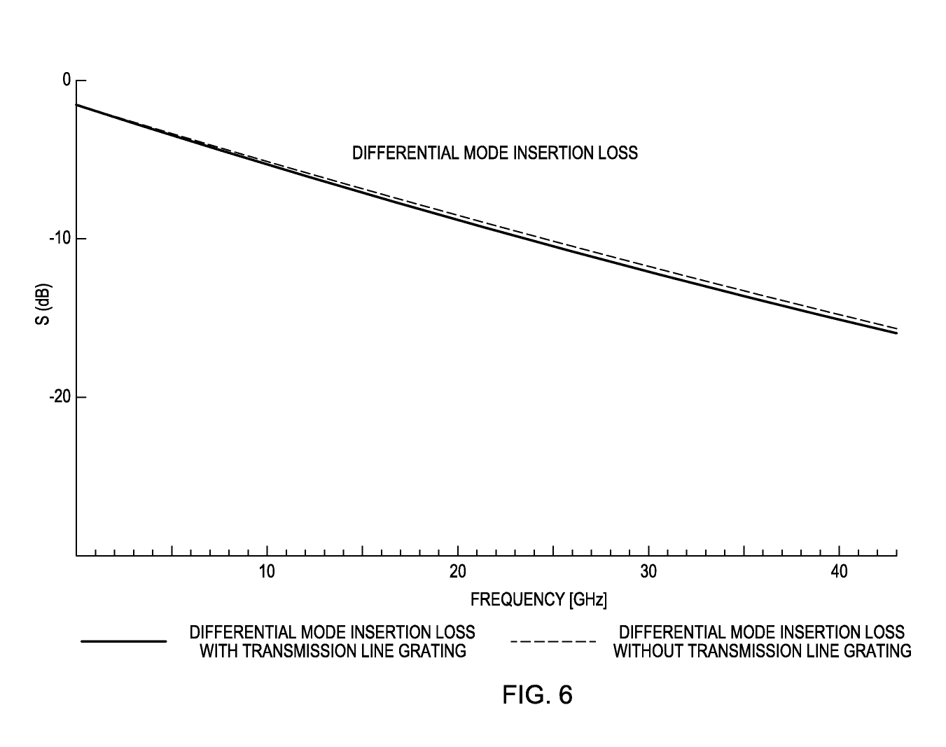

FIG. 6 is a graph of a simulation of differential mode insertion loss in differential transmission lines with and without a transmission line grating. The simulation of the insertion loss shown in a representative differential transmission lines with and without a transmission line grating is shown at various frequencies. The same length transmission lines are used for both simulations. The insertion loss is shown on the Y axis in dB and frequency is on the X axis in GHz. The simulation evaluates the insertion loss by differential mode signals with and without the transmission line grating. The graph of the simulated data shows there is little to no change in the differential mode signal with and without the transmission line grating.

Therefore, considering both FIG. 5 and FIG. 6, a large increase in the amount of the common mode insertion loss occurs at several frequencies with the transmission line grating. In a similar simulation of the differential mode insertion loss, there is little to no change in the differential mode insertion loss with the transmission line grating thus, maintaining the integrity of the differential mode signal while reducing common mode insertion loss with the transmission line grating.

Embodiments of the present invention suppress EMI by a design that uses the transmission line grating to filter out or suppress unwanted frequencies causing EM radiation. The design of a PCB using the transmission line grating reduces the common mode noise normally produced by the PCB. By reducing the common mode noise at a specific frequency in the PCB, the transmission line grating technique depicted reduces PCB related EMI.

What is claimed is:

1. A method of designing electronic circuit elements for frequency suppression of electromagnetic waves using a transmission line grating, the method comprising:
determining a frequency to be suppressed;
determining, in response to an electrical wavelength of the frequency to be suppressed, a length of a plurality of equal length sections of the differential transmission lines;
utilizing the frequency to be suppressed and in response to electronic circuit requirements, determine a set of properties for the plurality of equal length sections of the differential transmission lines; and
creating the transmission line grating with a plurality of alternating equal length sections of the differential transmission lines.

2. The method of claim 1, wherein the frequency to be suppressed is selected to reduce electromagnetic interference radiation from one or more harmonic frequencies.

3. The method of claim 1, wherein the properties of the plurality of equal length sections of the differential transmission lines include the materials used and the physical dimensions of the differential transmission lines.

4. The method of claim 3, wherein the physical dimensions of the plurality of equal length sections of the differential transmission lines are determined using the electrical circuit requirements including maintaining a uniform differential characteristic impedance in the differential transmission lines.

5. The method of claim 1, wherein the transmission line grating comprises alternating the sections of the plurality of equal length sections of the differential transmission lines wherein the equal length sections of the differential transmission lines have narrow line sections and wide line sections of the plurality of equal length sections.

6. The method of claim 1, wherein the length of each of the plurality of equal length sections of the differential transmission lines is determined to be one quarter of the wavelength of the frequency to be suppressed.

7. The method of claim 1, wherein the number of sections of the plurality of equal length sections of the differential transmission lines depends on either the electromagnetic frequency suppression or the space available on the electronic circuit device.

8. The method of claim 1, wherein the transmission line grating design is applied to a printed circuit board.

9. The method of claim 8, wherein the printed circuit board uses a strip-line design or micro-strip design for the differential transmission lines in the transmission line grating

10. A transmission line grating comprising:
a portion of the differential transmission lines, wherein the differential transmission lines includes a first line and a second line;
wherein the portion includes a plurality of first sections, wherein each first section includes a segment of the first line having a length and a first width and includes a segment of the second line having the length and the first width, wherein the segment of the first line and the segment of the second line of each first section are substantially parallel, and wherein the segment of the first line and the segment of the second line of each first section are separated by a first spacing;
wherein the portion includes a plurality of second sections, wherein each second section includes a segment of the first line having the length and a second width and includes a segment of the second line having the length and the second width, wherein the segment of the first line and the segment of the second line of each second section are substantially parallel, and wherein the segment of the first line and the segment of the second line of each second section are separated by a second spacing;
wherein the second width is larger than the first width; and
wherein one of the plurality of second sections is between two of the plurality of first sections.

11. The transmission line grating of claim 10, wherein the physical properties of the plurality of sections of the differential transmission lines include the materials used and the physical dimensions of the differential transmission lines.

12. The transmission line grating of claim 10, wherein the length of each section of the plurality of equal length sections of the differential transmission lines is equal to one quarter of the wavelength of the frequency to be suppressed.

13. The transmission line grating of claim 10, wherein the number of sections of the plurality of equal length sections of the differential transmission lines is determined by the electromagnetic radiation or the available space on the electronic circuit device.

14. The transmission line grating of claim 10, wherein the transmission line grating is used in a printed circuit board.

15. The transmission line grating of claim 10, wherein the printed circuit board uses a strip-line design or micro-strip design.

16. A transmission line grating comprising:
the differential transmission lines;
a portion of the differential transmission lines with a plurality of equal length sections;
the plurality of equal length sections with a plurality of first equal length sections and a plurality of second equal length sections;
the plurality of first equal length sections and the plurality of second equal sections each have a set of physical properties determined by a desired electrical performance including maintaining a uniform differential characteristic impedance; and the set of physical properties of the plurality of first equal length sections includes narrower equal width transmission lines with narrower spaces between the differential pair; and the set of physical properties of the plurality of second equal length sections includes wider equal width transmission lines with wider spaces between the differential pair; and
wherein one of the plurality of second sections is between two of the plurality of first sections.

17. The transmission line grating of claim 16, wherein the physical properties of the plurality of sections of the differential transmission lines include the materials used and the physical dimensions of the differential transmission lines.

18. The transmission line grating of claim 16, wherein the length of each section of the plurality of equal length sections of the differential transmission lines is equal to one quarter of the electrical wavelength of the frequency to be suppressed.

19. The transmission line grating of claim 16, wherein the transmission line grating is used in a printed circuit board.

20. The transmission line grating of claim 16, wherein the printed circuit board uses a strip-line design.
